(19) United States
(12) Patent Application Publication
(10) Pub. No.: US 2013/0122641 A1
(43) Pub. Date: May 16, 2013

(54) Method of Fabricating Buried Contacts of Solar Cell with Curved Trenches

(71) Applicants: Fang-Chi Hsieh, Xuzhou (CN); Li-Karn Wang, Taipei City (TW)

(72) Inventors: Fang-Chi Hsieh, Xuzhou (CN); Li-Karn Wang, Taipei City (TW)

(73) Assignees: NATIONAL TSING HUA UNIVERSITY, Hsinchu (TW); JIANGSU AIDE SOLAR ENERGY TECHNOLOGY CO.,LTD, Xuzhou (CN)

(21) Appl. No.: 13/352,541

(22) Filed: Jan. 18, 2012

(30) Foreign Application Priority Data
Nov. 10, 2011 (TW) 100141107

(51) Int. Cl. H01L 31/18

(52) U.S. Cl. 438/95; 257/E31.003

(57) ABSTRACT

A solar cell having buried contacts is provided. Curved trenches are formed on a surface of a Si substrate to form the buried contacts. The curved trenches have deep depths with wafer break prevented. The buried contacts have good efficiency on collecting electrons obtained from conversion by the longer wavelength light. The present invention is fit for mass production with a high yield, a simple fabrication procedure, a low cost and a good performance.

### TECHNICAL FIELD OF THE INVENTION

The present invention relates to a solar cell; more particularly, relates to etching out curved trenches on a silicon (Si) substrate through wet or dry etching for obtaining a Si substrate having buried contacts.

### DESCRIPTION OF THE RELATED ARTS

A buried-contact solar cell usually has a trench array on a front surface of a solar cell at an illuminated side for forming metal contacts inside the trenches by plating process. An example of such a device is diagrammatically shown in FIG. 6, where the solar cell has a P-N junction and buried contacts 15. The solar cell has a p-type Si substrate. Through laser scribing, straight-line trenches are formed on a front surface of the Si substrate. Near-surface areas around contacts in the trenches are formed into a first n-type layer (n⁺⁺ layer) having a higher doping concentration; and the other near-surface areas outside the trenches are formed into a second n-type layer (n+ layer) having a lower doping concentration. As shown in FIG. 6, a method for fabricating this kind of selective emitter and buried contacts is to form a shallow second n-type layer 12 through diffusing phosphorous into a near-surface area of a p-type Si substrate 11 having a low doping concentration. Then, a passivation layer and an anti-reflective layer (or an anti-reflective layer 13 having passivation function) are grown. Then, by using laser or in a mechanical way (without photolithography), trenches, i.e. trench array, are scribed on the surface. The near-surface areas around the contacts in the trenches are formed into a more highly doped first n-type layer 14 through diffusing phosphorous. Then, metal contacts are fabricated in the trenches to form buried contacts 15. Another method for fabricating metal contacts is to coat a phosphorous-containing silver paste in trenches. Then, phosphorous is diffused into the near-surface areas in the trenches through annealing to form a first n-type layer 14. The cell shown in FIG. 6 has a back contact 16; a back surface field (BSF) layer 17 on back surface; and a textured surface 18 on the front surface for light trapping with improved photoelectric conversion. The scribed trenches have a width of ten's of micrometers (μm) and a depth of several times as the width of the trench. The buried-contact solar cell thus fabricated is reported to have a photoelectric conversion efficiency of more than 22%.

Another method for fabricating selective emitter and buried contacts is done through one-time diffusion to form both a first n-type layer and a second n-type layer. At first, a dielectric layer (e.g. a silicon nitride or silicon oxide layer) is coated on a textured front surface of a p-type Si substrate. Then, the dielectric layer is patterned and then the Si substrate is etched to form trenches at the areas uncovered by the dielectric, where trench areas are left uncovered by the dielectric and the other surface areas are covered by the dielectric. Then, the Si substrate is put into a diffusion furnace to form n-type layers. Because the surface areas outside the trenches are covered with the dielectric layer having a proper thickness, their doping concentrations are lower than those of the trench areas, and a selective emitter structure is thus formed. At last, metal is put into the trenches to form buried contacts.

The buried-contact solar cell's conversion efficiency induced by the longer wavelength light is affected by depths of the trenches. Generally, higher efficiency is obtained with deeper trenches. Traditionally, trenches formed by laser scribing are geometrically straight lines. In FIG. 7, the straight-line fingers 22 of buried contacts on a surface of a Si substrate are separated by busbars 21. If the trenches are too deep, wafer break may easily happen to result in a low yield.

Use of the buried contacts has the following benefits: First, the masking effect of the metal contact can be reduced, and, in this case, an amount of resistance comparable to traditional screen-printed contacts can be still obtained because the contacts are buried deep inside the Si substrate in spite of narrower line widths of the buried contacts. Secondly, because the line widths of the buried contacts are narrower, the intervals between the buried contacts can be made smaller than those between traditional screen-printed contacts. Accordingly, electrons obtained from conversion in the buried-contact solar cell by absorbing optical energy thus have a shorter average distance to move to the contacts. Hence, internal resistance of the buried-contact solar cell is greatly reduced, and thereby the value of fill factor (F.F.) is increased with photoelectric conversion efficiency enhanced as well. Moreover, because the contacts are located in tens or more micrometers deep in the Si substrate, many electrons obtained from conversion by the longer wavelength light can more easily move to the contacts; and, thus, more electrons are collected by the contacts with a result of a higher short-circuit current. With implementation of the selective emitter structure, open-circuit voltage is increased. All these quite benefit the photoelectric conversion of a solar cell. Noteworthy is that the n⁺⁺ layer made to induce a low sheet resistance around the buried contacts is used to reduce contact resistance between metal and semiconductor for achieving a high F.F as well.

The trenches, i.e. trench array, scribed by laser or in a mechanical way are in fact not fit for mass production, especially for scribing out a great number of trenches on a large-scale Si substrate; for it takes time and the throughput would be low. The reasons for such a situation are as follows: If laser scribing is used, scribing speed would not be high enough for mass production; if multiple machines for laser scribing are used, production cost would be too high; if a mechanical knife is used, the problem of slow scribing speed would remain; and, even if a mechanical knife array is used, the knives would scribe the Si substrate back and forth causing an inevitable slow process problem. Furthermore, such mechanical scribing processes that are intended to form a large number of closely-spaced trenches would make the wafer fragile, where a stress would thus be produced breaking the fragile wafer and resulting in a low yield.

As mentioned above, depths of trenches would affect conversion efficiency of the longer wavelength light in the buried-contact solar cell. In general, deeper trenches would obtain a better efficiency for the contacts on collecting electrons obtained by conversion of the longer wavelength light. However, deep trenches would have high possibility of resulting in wafer break. Hence, the prior arts do not fulfill all users' requests on actual use.

### SUMMARY OF THE INVENTION

The main purpose of the present invention is to provide a method for mass producing a Si solar cell having buried contacts with a high yield.

To achieve the above purpose, the present invention is a method of fabricating buried contacts of a solar cell with curved trenches, where an etchant-resistant material is coated on a front surface of a Si semiconductor substrate through printing; after curing, a mask layer having a pattern is obtained; areas covered by the mask layer on the front surface of the Si substrate is not etched by an etchant, while the other areas uncovered by the mask layer on the front surface is etched; a plurality of curved trenches is thus formed on the front surface of the Si semiconductor substrate; geometrically, at least one of the curved trenches comprises a trace of a straight-line section with a length not longer than two fifth of the smallest dimension of the Si semiconductor substrate; the Si semiconductor substrate is a doped substrate of a specific electric type; depth of each curved trench is at least one sixth of a thickness of the doped Si semiconductor substrate; and each curved trench has an opening that is at least 30 μm wide. Accordingly, a novel method of fabricating buried contacts of a solar cell with curved trenches is obtained.

### BRIEF DESCRIPTIONS OF THE DRAWINGS

The present invention will be better understood from the following detailed descriptions of the preferred embodiments according to the present invention, taken in conjunction with the accompanying drawings, in which

FIG. 1 is the diagrammatic view showing a solar cell having the buried contacts fabricated according to the present invention;

FIG. 2 is the plan view showing the metal contact layout on the front surface of a solar cell using the first preferred embodiment;

FIG. 3 is the plan view showing the metal contact layout on the front surface of a solar cell using the second preferred embodiment;

FIG. 4 is the first process flow view showing the fabrication of the solar cell;

FIG. 5 is the second process flow view showing the fabrication of the solar cell;

FIG. 6 is the structural view of the prior art; and

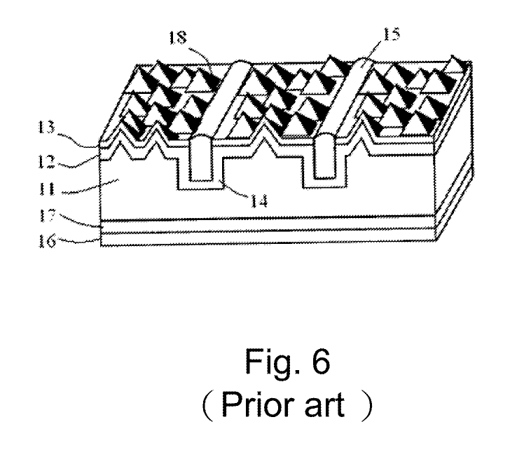

FIG. 7 is the plan view showing the metal contact layout of the prior art.

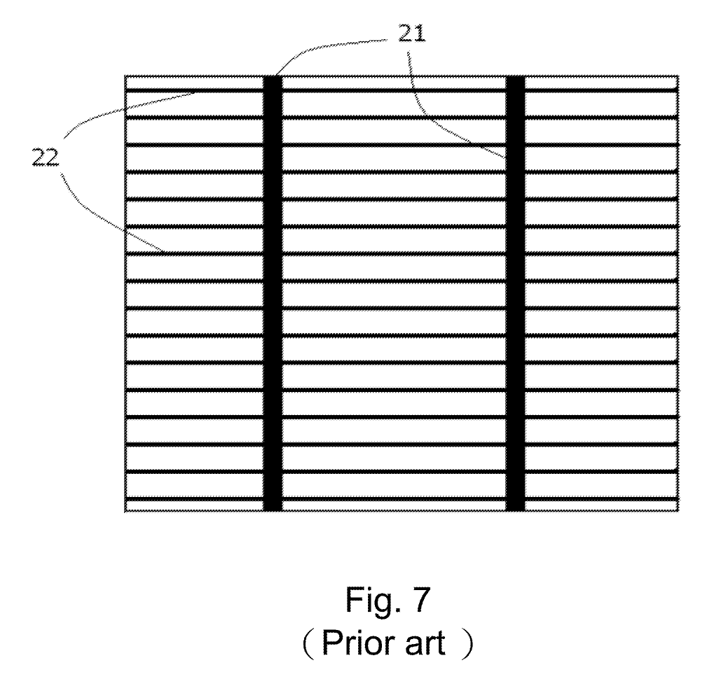

### DESCRIPTION OF THE PREFERRED EMBODIMENTS

The following descriptions of the preferred embodiments are provided to understand the features and the structures of the present invention.

The present invention is a method of fabricating buried contacts of a solar cell with curved trenches. An etchant-resistant material is coated on a front surface of a silicon (Si) semiconductor substrate through printing. After curing, a mask layer having a pattern is obtained. Areas covered by the mask layer on the front surface of the Si semiconductor substrate is not etched by an etchant; and, the other areas uncovered by the mask layer on the front surface of the Si semiconductor substrate is etched. Thus, a plurality of curved trenches are formed on the front surface of the Si semiconductor substrate. Therein, geometrically, at least one of the curved trenches comprises a trace of straight-line section with a length not longer than two fifth of the smallest dimension of the Si semiconductor substrate; the Si semiconductor substrate is a doped substrate of a specific electric type; depth of each curved trench is at least one sixth of thickness of the Si semiconductor substrate; and, each curved trench has an opening at least 30 micrometers (μm) wide.

After etching out the curved trenches, a series of processes are followed, at least including diffusing a doping element to form a thin doped layer on the front near-surface area; coating a dielectric layer on the front surface; filling a conductive material into the curved trenches; coating a contact on a back surface of the Si semiconductor substrate; sintering; and processing edge isolation. Consequently, the solar cell is finished with buried contacts thus formed.

In an embodiment of the present invention, the front surface of the Si semiconductor substrate is textured and has a dielectric layer. The back surface has a back surface field (BSF) layer. Inside the Si semiconductor substrate, the front near-surface area contains a doping element to obtain a P-N junction. After forming the curved trenches, a doping element is diffused into the Si semiconductor substrate at high temperature. Thus, at the curved trench area, a doped layer, whose electric type is opposite to the Si semiconductor substrate, is formed. The doping element in the doped layer has a concentration not lower than that in the doped layer at non-etched areas on the front surface of the Si semiconductor substrate.

Therein, the dielectric layer on the front surface of the Si semiconductor substrate at least contains silicon dioxide (SiO₂), silicon nitride or silicon oxynitride; and, after the Si semiconductor substrate is doped through diffusion at high temperature, the resultant silicon oxide and said dielectric layer are removed.

In another embodiment of the present invention, areas outside the curved trenches on the front surface of the Si semiconductor substrate have a barrier layer to hinder a doping element from diffusing into the Si semiconductor substrate. As the doping element is diffused onto surface of the curved trenches on the front surface of the Si semiconductor substrate, a first doped layer is formed, where the first doped layer has an electric type opposite to the Si semiconductor substrate. At the same time, a second doped layer is obtained at non-etched areas on the front surface outside the curved trenches. The first doped layer has a doping concentration not lower than that of the second doped layer.

Therein, after the first and the second doped layers are formed on the Si semiconductor substrate, a dielectric layer is grown on the front surface of the Si semiconductor substrate. The dielectric layer at least contains silicon nitride or comprises a first dielectric layer and a second dielectric layer. The first dielectric layer at least contains silicon oxide and the second dielectric layer at least contains silicon nitride, where the silicon oxide is SiO₂ or SiOₓ, _{x≠2}.

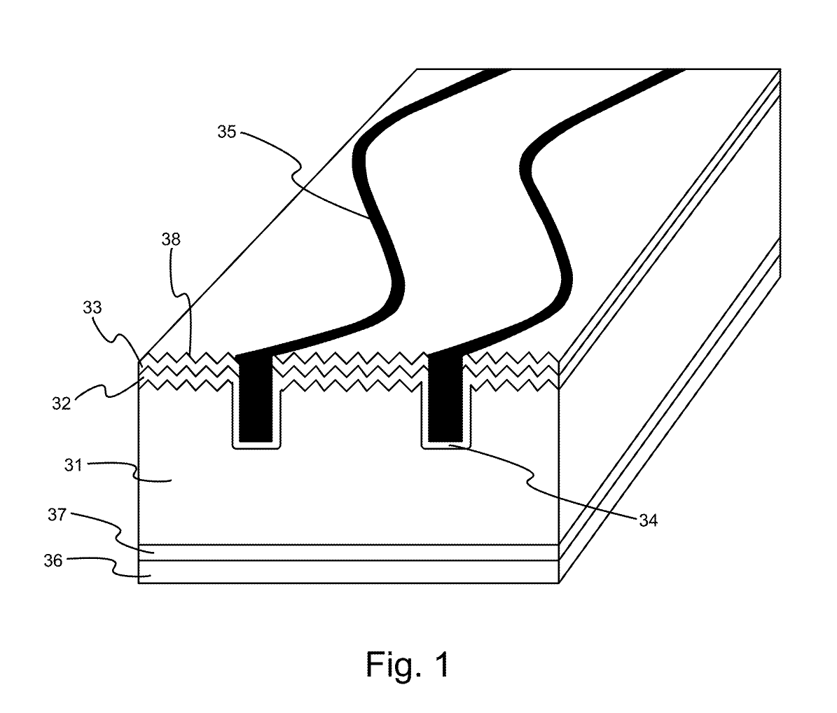

Please refer to FIG. 1 to FIG. 3, which are a diagrammatic view showing buried contacts fabricated according to the present invention; and plan views showing the metal contact layout of the solar cells using a first and a second preferred embodiments. As shown in the figures, a solar cell comprises a p-type Si substrate 31, a first n-type layer 34, a second n-type layer 32, an anti-reflective layer 33, a plurality of buried contacts 35, a BSF layer 37 and a back contact 36. Therein, the anti-reflective layer 33 is solely made of silicon nitride providing surface passivation function; or, is formed by growing and combining a SiO₂ layer and a silicon nitride layer. For growing SiO₂, a method selected from thermal oxidation, chemical vapor deposition, evaporation and sputtering, or a method of dipping the Si substrate in a chemical solution is used with surface passivation; and, for growing silicon nitride, a method selected from chemical vapor deposition, evaporation and sputtering is used to provide surface passivation and anti-reflection. For achieving light trapping effect, the p-type Si substrate 31 has a textured surface 38. The first and the second n-type layers 34,32 are formed under a surface of the p-type Si substrate 31 at an illuminated side through diffusing an n-type doping element at a high temperature above 700° C. in a furnace. Therein, the first n-type layer 34 has a doping concentration higher than that of the second n-type layer 32.

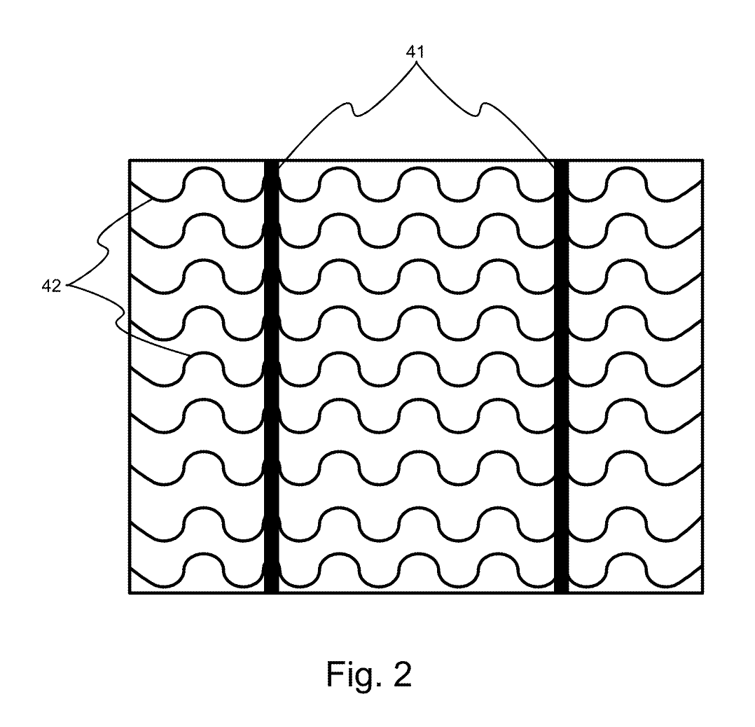

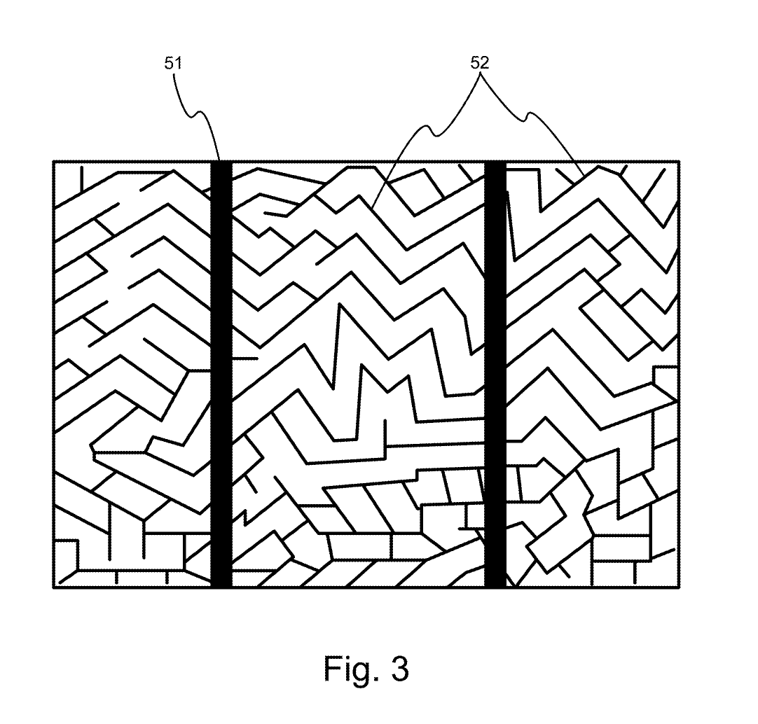

The buried contact wires in FIG. 1 can be distributed as non-interlaced geometrical curves, where lines of the curved trenches geometrically comprise curves as shown in FIG. 2, which are not straight-line sections. Or, the buried contact wires can be distributed as interlaced geometrical straight lines, where lines of the curved trenches geometrically comprise straight sections as shown in FIG. 3. Furthermore, at least one turning of a straight line can be found at a one-square-centimeter surface area between adjacent busbars of the Si substrate 31; and, the turning forms an included angle of two straight-line sections, where the included angle has a degree not between 160° and 200°. In FIG. 2 and FIG. 3, the busbars 41,51 do not necessarily have trenches as deep as the finger-line trenches 42,52.

Besides, the non-straight-line curves can have at least one intersection and the curved trenches can be geometrically a mixture of non-straight-line curves and straight-line sections.

The ‘straight line’ or ‘straight-line section’ mentioned in the present invention means a section of continuous line, where, by fitting with a geometrical straight line, deviation between the continuous line and the geometrical straight line is smaller than ±1 millimeter (mm) over a length of 5 centimeters (cm).

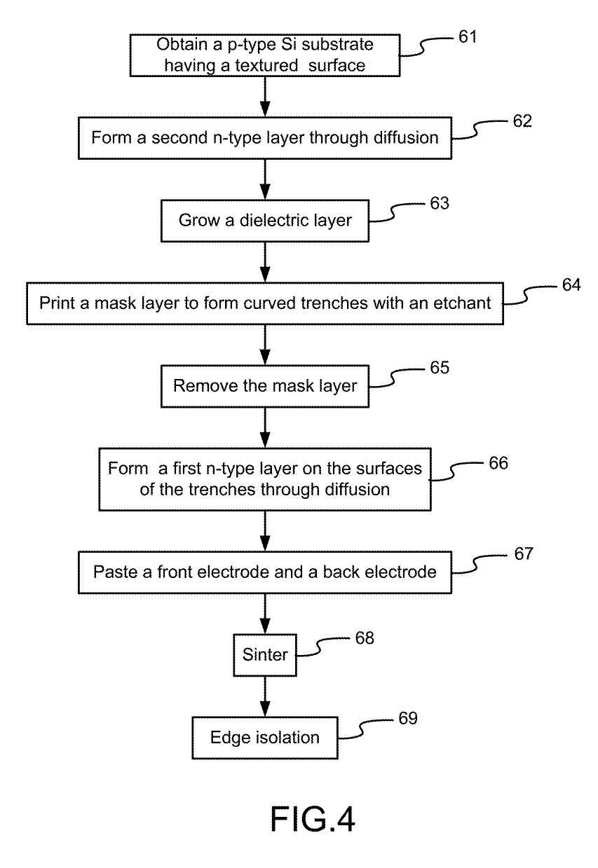

Please refer to FIG. 4, which is a first process flow view showing fabrication of a solar cell. As shown in the figure, for fabricating a solar cell having buried contacts according to the present invention, a p-type Si substrate is obtained to be etched for forming a textured surface 61. An n-type doping element is then diffused into the Si substrate in a furnace at a temperature higher than 700° C. to form a shallow second n-type layer, an n+ layer, at a near-surface area of the Si substrate at an illuminated side 62. A dielectric layer is grown above the second n-type layer 63, where the dielectric layer is used to prevent an n-type doping element from diffusing again at a later time. Then, a mask layer is coated on the Si substrate through screen printing or cylinder printing for resisting an etchant. A pattern is thus obtained on the Si substrate. When the Si substrate is dipped in the etchant, the silicon on the surface area uncovered by the mask layer is etched to form curved trenches on front-surface areas of the Si substrate 64. After forming the curved trenches, the mask layer is removed 65. Then, the Si substrate is put into a diffusion furnace at a temperature higher than 700° C. to use a n-type doping element to form a first n-type layer, an n⁺⁺ layer, on the surfaces of the trench areas 66. The doping concentration of the n⁺⁺ layer is higher than that of the n⁺ layer. At last, an electrically-conductive material is pasted in the curved trenches and on busbar areas to be sintered at high temperature for forming curved buried contacts and busbars. Concerning back contact of the Si substrate, an electrically-conductive material is pasted to be sintered together with the buried contacts and the busbars to further form a back surface field (BSF) layer, a P⁺ layer, on the back surface of the Si substrate for increasing an open-circuit voltage of the solar cell 67,68. After finishing the above sintering process, edge isolation is processed 69 to complete the solar cell fabrication. It is noted that the edge isolation can be processed right after the diffusion process forming a first n-type layer.

Therein, the n-type doping element is selected from the VA group, whose source is POCl₃, P₂O₅, PH₃ or other solid or gaseous phosphorus compound; or a material containing As or Sb. The etchant can be a chemical solution for wet etching or a chemical gas for dry etching. The material of the mask layer is etchant-dependent which can be a pasting material having silicon oxide or other dielectric (e.g. a polymer); a metallic compound; or a pasting material containing a metal. The BSF layer is formed through sintering the back contact; or, is formed through diffusion or thin-film coating.

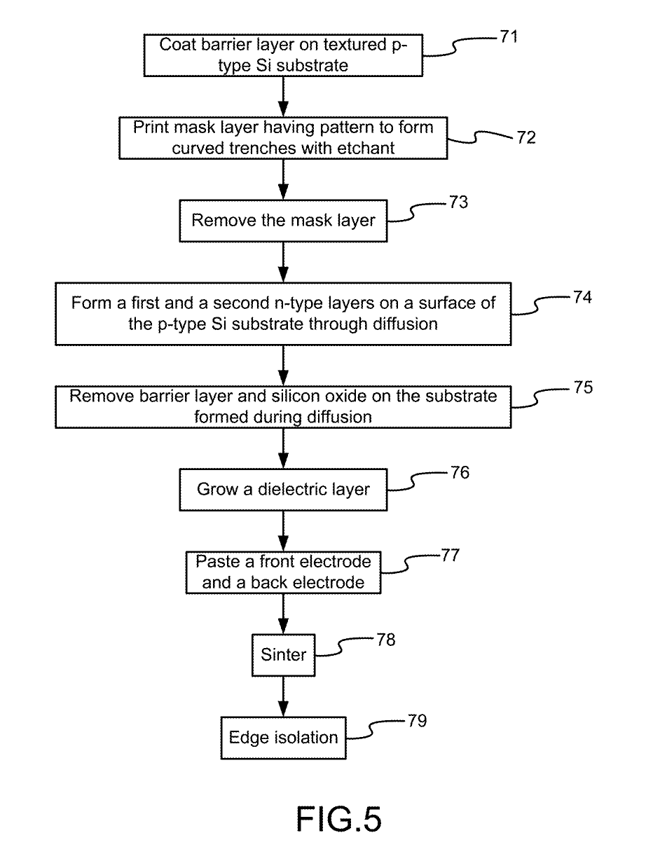

Please refer to FIG. 5, which is a second process flow view showing fabrication of a solar cell. As shown in the figure, for fabricating a solar cell having buried contacts according to the present invention, after texturization, a p-type Si substrate is coated with a barrier layer 71 for preventing diffusion of an n-type doping element. Then, a mask layer having a pattern is formed on the Si substrate through screen printing or cylinder printing for resisting an etchant. The Si substrate is then dipped in the etchant to form curved trenches 72 on front-surface areas uncovered by the mask layer. After forming the curved trenches, the mask layer is removed 73. Then, the Si substrate is put into a furnace at a temperature higher than 700° C. to diffuse an n-type doping element into the Si substrate to form a first n-type layer, an n⁺⁺ layer, at surface areas of the trenches, and at the same time to form a shallow second n-type layer, an n⁺ layer, at surface of the Si substrate outside the trenches 74. Then, the barrier layer and resultant silicon oxide obtained on the surface of the Si substrate through diffusion, e.g. phosphorous-containing silicon oxide, are removed 75. Then, a dielectric layer is grown 76 and front and back contacts are pasted 77. At last, after sintering 78, edge isolation is processed 79. Thus, the solar cell is fabricated. It is noted that the edge isolation can be processed right after the diffusion process forming a first n-type layer and a second n-type layer.

The mask layer can be also formed on a surface of an n-type Si substrate at an illuminated side through screen printing or cylinder printing to further forming the curved trenches. That is, the fabrication of a buried contact solar cell with curved trenches can be processed on an n-type Si substrate.

The curved trenches are not fabricated through a time-consuming photolithographic process, a laser scribing process. It is emphasized here that the curved trenches are not easy to be fabricated by using the laser and mechanical scribing methods. Mass production is thus made possible by using the method according to the present invention. Besides, costs of facilities required for fabricating the curved trenches are low. The trenches not only can be formed through a wet etching method to etch the Si uncovered by a mask layer; but also can be formed through a dry etching method at areas uncovered by a mask layer.

To sum up, the present invention is a method of fabricating buried contacts of a solar cell with curved trenches, where curved trenches are formed through wet etching or dry etching with wafer break prevented; the curved trenches have deep depths; buried contacts in deep trenches have good efficiency on collecting electrons obtained from conversion by the longer wavelength light; and the present invention is fit for mass production with a high yield, a simple fabrication procedure, a low cost and a good performance.

The preferred embodiments herein disclosed are not intended to limit the scope of the invention. Therefore, simple modifications or variations belonging to the equivalent of the scope of the claims and the instructions disclosed herein for a patent are all within the scope of the present invention.

What is claimed is:

1. A method of fabricating buried contacts of a solar cell with curved trenches, said method obtaining an etchant-resistant material to be coated on an end surface (front surface) of a silicon (Si) semiconductor substrate through printing to obtain a mask layer and using said mask layer after curing to prevent first areas from being etched by an etchant and to etch second areas so as to obtain a plurality of curved trenches on said end surface of said Si semiconductor substrate,
wherein said first areas are areas covered by said mask layer on said end surface of said Si semiconductor substrate and said second areas are areas uncovered by said mask layer on said end surface of said Si semiconductor substrate;
wherein, geometrically, at least one of said curved trenches comprises a trace of straight-line section with a length not longer than two fifth of the smallest dimension of said Si semiconductor substrate;
wherein said Si semiconductor substrate has a specific electric type;
wherein depth of each one of said curved trenches is at least one sixth of thickness of said Si semiconductor substrate; and
wherein each of said curved trenches has an opening at least 30 micrometers (μm) wide.

2. The method according to claim 1,
wherein, geometrically, said curved trenches comprise a plurality of curves being not straight-line sections.

3. The method according to claim 2,
wherein said curves have at least one intersection.

4. The method according to claim 1,
wherein, geometrically, each one of said curved trenches comprises a plurality of straight-line sections.

5. The method according to claim 4,
wherein said straight-line sections have at least one intersection.

6. The method according to claim 1,
wherein, geometrically, said curved trenches are a mixture of non-straight-line curves and straight-line sections.

7. The method according to claim 1,
wherein, geometrically, lines of said curved trenches comprise a plurality of straight-line sections;
wherein at least one turning of a straight line is found at a one-square-centimeter surface area between adjacent busbars of said Si semiconductor substrate; and
wherein said turning forms an included angle of two straight-line sections, said included angle having a degree not between 160° and 200°.

8. The method according to claim 1,
wherein said etchant is selected from a group consisting of a chemical gas used in dry etching and a chemical solution used in wet etching.

9. The method according to claim 1,
wherein said etchant-resistant material is a paste having a material selected from a group consisting of silicon oxide, a polymer, a metal and a metal compound.

10. The method according to claim 1,
wherein said end surface of said Si semiconductor substrate is textured;
wherein areas outside said curved trenches on said end surface of said Si semiconductor substrate have a barrier layer to hinder a doping element from diffusing into said Si semiconductor substrate;
wherein a first doped layer is obtained as said doping element is diffused onto surface areas of said curved trenches, said first doped layer has an electric type opposite to said Si semiconductor substrate, and, at the same time, a second doped layer is obtained on non-etched areas of said end surface not belonging to the surface areas of said curved trenches; and
wherein said first doped layer has a doping concentration not lower than that of said second doped layer.

11. The method according to claim 10,
wherein, after said first and said second doped layers are obtained on said Si semiconductor substrate, a dielectric layer is obtained on said end surface of said Si semiconductor substrate.

12. The method according to claim 10,
wherein, after said first and said second doped layers are obtained on said Si semiconductor substrate, a first dielectric layer and a second dielectric layer are obtained on said end surface of said Si semiconductor substrate.

13. The method according to claim 12,
wherein said first dielectric layer at least contains silicon oxide;
wherein said second dielectric layer at least contains silicon nitride; and
wherein said silicon oxide is selected from a group consisting of SiO₂ and SiOₓ, _{x≠2}.

14. The method according to claim 1,
wherein said end surface of said Si semiconductor substrate is textured and has a dielectric layer;
wherein said Si semiconductor substrate under said front surface contains a doping element to obtain a P-N junction;
wherein, after said curved trenches are obtained, a doping element is diffused into said Si semiconductor substrate at high temperature, a doped layer is formed at the surface areas of said curved trenches, and said doped layer has an electric type opposite to said Si semiconductor substrate; and
wherein said doping element in said doped layer has a concentration not lower than that in said doped layer at non-etched areas on said end surface of said Si semiconductor substrate.

15. The method according to claim 14,
wherein said dielectric layer on said end surface of said Si semiconductor substrate at least contains an element selected from a group consisting of silicon dioxide, silicon nitride and silicon oxynitride.

16. The method according to claim 14,
wherein, after said Si semiconductor substrate is doped through diffusion at high temperature, resultant silicon oxide and said dielectric layer formed on said end surface of said Si semiconductor substrate are removed.

17. The method according to claim 1,
wherein a solar cell having buried contacts made through said method is obtained with said curved trenches and a second doped layer on said end surface of said Si semiconductor substrate; and
wherein, after obtaining a dielectric layer on said end surface of said Si semiconductor substrate, said solar cell is finished through filling a conductive material into said trenches on said end surface, pasting a conductive material on another end surface (back surface) of said Si semiconductor substrate, obtaining a first doped layer, and sintering.

18. The method according to claim 1,
wherein a solar cell having buried contacts made through said method is obtained with said curved trenches and a first and a second doped layers on said end surface of said Si semiconductor substrate; and
wherein, after obtaining a dielectric layer on said end surface of said Si semiconductor substrate, said solar cell is finished through filling a conductive material into said trenches on said end surface, pasting a conductive material on another end surface (back surface) of said Si semiconductor substrate, and sintering.

19. The method according to claim 1,
wherein another end surface (back surface) of said Si semiconductor substrate has a back surface field (BSF) layer.

20. The method according to claim 19,
wherein said BSF layer is obtained through a process selected from a group consisting of diffusing, coating and sintering said another end surface of said Si semiconductor substrate.
